(19) United States
(12) Patent Application Publication
(10) Pub. No.: US 2008/0101627 A1
(43) Pub. Date: May 1, 2008

(54) NOISE INDICATION APPARATUS AND METHOD FOR DETECTING NOISE

(76) Inventors: Ming-Hu Lin, Taipei (TW); Ping-Yuan Liu, Taipei (TW); Chich-Chang Lin, Taipei (TW)

Correspondence Address: Connolly Bove Lodge & Hutz, LLP, P.O.Box 2207, Wilmington, DE, 19899-2207, US

(21) Appl. No.: 11/553,033

(22) Filed: Oct. 26, 2006

(51) Int. Cl. H04B 15/00; H04R 29/00; H03G 3/00

(52) U.S. Cl. 381/94.7; 381/107; 381/56

(57) ABSTRACT

A noise indication apparatus and a method for detecting noise comprise a sound volume detection module and warning unit. The sound detection module can pick up a sound signal and then detect the sound volume thereof after the sound indication module is connected to an electronic device capable of outputting the sound source signal. Furthermore, different warning units are driven depending on the sound volume to warn whether the sound volume is beyond a hearing capability protection standard so as to prevent a user from the hearing damage due to overlarge sound volume.

### BACKGROUND OF THE INVENTION

1. Field of the Invention

The present invention relates to a warning apparatus and a method for detecting sound volume and generating different signals, and more particularly to a noise indication apparatus and a method for detecting noise capable of detecting the sound volume output to a sound emitting element such as an earphone or speaker and generating different warning signals according to different sound volumes.

2. Description of Related Art

Decibel (dB) is a unit for sound intensity and sound volume, sound whose volume between the ranges of 0 to 140 dB can be heard by a general human's ears.

Noise is the most reason for a human to lose his hearing capability. In fact, not only a worker usually exposed himself in a noise environment but also a general people can be exposed in a variety of different degree noises such that different degrees of hearing loss are unconsciously caused. Besides, noise can influence not only hearing capability but also human health such as heart and blood vessel conditions and sleep quality.

Noises existing in a human life possibly are pop music sound which might reach beyond 120 dB, train passing sound 100 dB, truck passing sound 85 dB, vacuum cleaner sound 70 dB, normal conversation sound 60 dB, slowly driven car sound 50 dB and quite office sound approximately 40 dB. A research points out that a general hearing capability protection standard is that the ear cannot exposed continuously under the circumference of 90 dB over 8 hours and 95 dB over 4 hours, or it will cause the hearing damage easily.

Accompanying the development of technology, electronic products bring living convenience gradually. For example, a walkman and a MP3 player are portable. A user always adjust the sound volume of a walkman or MP3 player louder for being able to listen to music clearly when he is in a noisy environment. But, because an earphone is worn closely to human ears, if the human ears are exposed in a large sound volume environment in a long term, the user will get used to the larger sound volume and he will expose himself in a noisy environment unconsciously. Nevertheless, if there is an apparatus capable of warning the user to allow him to know whether a sound volume is inside the range of a hearing protection standard, the hearing damage can be avoided.

### SUMMARY OF THE INVENTION

For solving the problems mentioned above, the present invention is proposed. A noise indication apparatus and a method for detecting noise according to the present invention is to pick a sound signal to detect the sound volume thereof when the sound signal input from an input end of a sound source and generate different signals warning depending on the volume thereof to notify a user and further to prevent the user from being in a high sound volume environment to cause the hearing damage.

A noise indication module according to the present invention mainly comprises a sound volume detection module and a warning unit.

The sound volume detection module comprises a memory module, signal processing unit and comparison unit. The memory module is used for storing one and more than one preset dB value. The signal processing unit is used for picking an analog sound signal input from an input end of a sound source and converting it to a digital sound source signal taking dB value as a unit. The comparison unit is used for comparing the dB value of the digital sound source signal obtained from the signal processing unit with the preset dB value stored in the memory module and generating a driving signal according to a comparison result to drive the warning unit.

The main object of the present invention is to provide a noise indication apparatus with a sound volume detection module, in which the sound volume detection module can used for detecting the volume of input sound volume and generating a driving signal to drive a warning unit to generate different warning signals depending on the value of sound volumes. A user can know whether the sound volume is beyond hearing capability protection standard from the different warning signals. Whereby, the hearing capability of the user can be protected and further to prevent the user from being in high sound volume environment to cause hearing damage.

Another object of the present of the present invention is to provide a noise indication apparatus capable of being connected to an electronic device such as a walkman or a MP3 player and a sound emitting element such as an earphone or speaker, capable of detecting sound volume even if output from a conventional audio-visual player such as a walkman, MP3 or MD.

### BRIEF DESCRIPTION OF THE DRAWINGS

The present invention can be more fully understood by reference to the following description and accompanying drawings, in which:

FIG. 1 is a perspective view, showing a noise indication apparatus according to the present invention;

FIG. 2 is a block diagram, showing a noise indication apparatus of a first preferred embodiment according to the present invention;

FIG. 3 is a flow chart of a method for detecting noise according to the present invention;

FIG. 4 is a block diagram, showing a noise indication apparatus of a second preferred embodiment according to the present invention;

FIG. 5 is a block diagram, showing a noise indication apparatus of a third preferred embodiment according to the present invention; and

FIG. 6 is a block diagram, showing a noise indication apparatus of a fourth preferred embodiment according to the present invention;

### DETAILED DESCRIPTION OF THE PREFERRED EMBODIMENTS

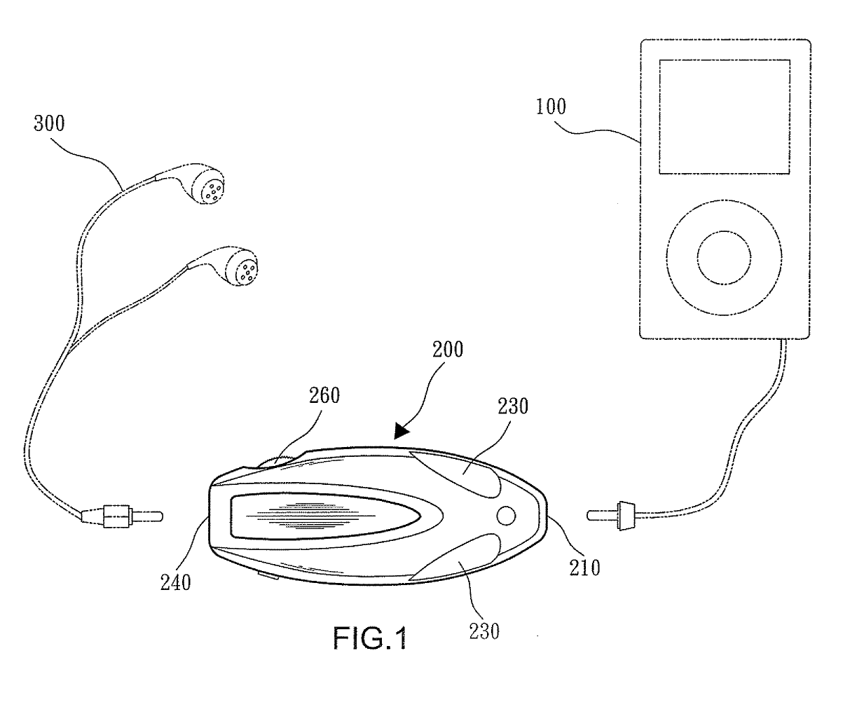

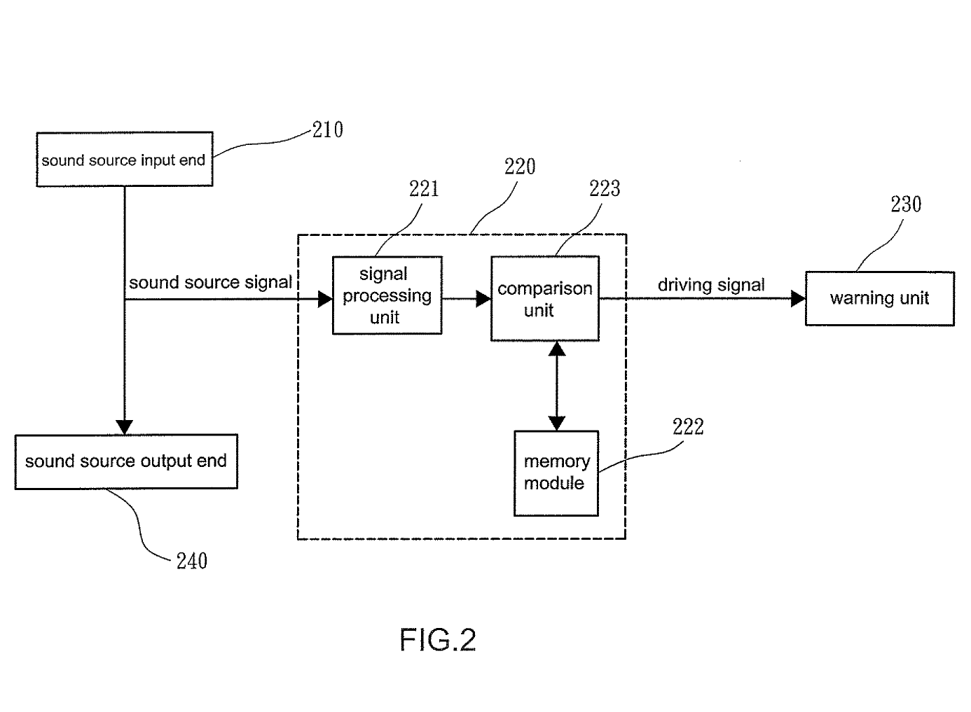

First, please refer to FIGS. 1 and 2. FIGS. 1 and 2 respectively are a prospective view and a block diagram of a first preferred embodiment of the present invention. A noise indication apparatus 200 comprises a sound source input end 210, sound volume detection module 220, warning unit 230 and sound source output end 240. The sound source input end 210 can be used for connecting to a music player 100 that can be a sound emitting electronic device, for example, walkman or MP3 player. The sound source output end 240 is used for connecting a sound emitting element 300 that can be an earphone or speaker. The sound volume detection module 220 is electrically connected to the sound source input end 210 to pick up an analog sound source signal input via the sound source input end 210 and convert it to be a digital sound source signal taking dB value as a unit, and compares it with a preset dB value to output a driving signal depending on the comparison result. The warning unit 230 is a display element that can display word, graph, signal and etc or a sound emitting element that can give off sound. Here, the sound emitting element can be an amplifier, speaker and etc and the display element can be at least one LED or a luminescent element. The warning unit 230 is electrically connected to the sound volume detection module 220 to receive the driving of the driving signal so as to display a warning sign or give off warning sound.

Next, please refer to FIG. 2. The sound volume detection module 220 is electrically connected between the sound source input end 210 and the warning unit 230. The sound volume detection module comprises a memory module 222, signal processing module 221 and comparison unit 223, in which the memory module 222 is used for storing one and more than one preset dB value, for example, 84 dB, 89 dB and 99 dB; the dB values mentioned above are only taken as an example, they can be adjusted to other preset dB values depending on a different need.

The signal processing unit 221 is an analog/digital converter used for converting an analog sound source signal to a digital signal and generating a dB value and the dB value is taken as a unit representing source value.

The comparison unit 223 is used for comparing the dB value generated from the signal processing unit 221 with the preset dB value and outputting a driving signal according to a comparison result. The driving signal can drive the warning unit 230 connected with the sound volume detection module 220 to enable the warning unit 230 to generate a warning signal, which is a warning sign or warning sound.

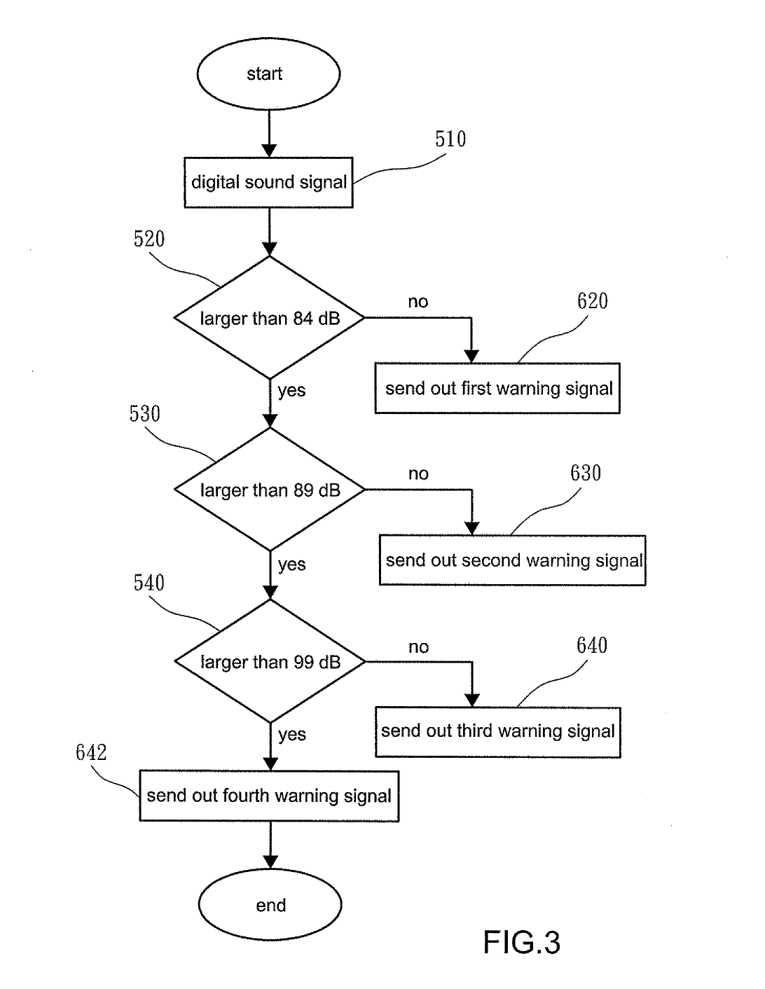

Connecting a music player such as walkman or MP3 player the sound source input end 210 of the noised indication apparatus 210 combined by the components mentioned above, the sound volume detection module 220 electrically connected to the sound source input end 210can pick up an input analog sound source signal and convert it to be a digital sound source signal taking dB as a unit. The converted digital sound source signal (Step 510) is transferred to the comparison unit 223 to compare with the preset dB value in the memory module 222 as FIG. 3 shows to judge whether the digital sound source signal is larger than 84 dB (Step 520). If no, a driving signal is output to drive a first warning signal (Step 620; if yes, continue to judge whether the sound source signal is larger than 89 dB (Step 530). If no, output a driving signal to drive a second warning signal (Step 630); if yes, continue to judge whether the sound source signal is larger than 99 dB (Step 540). If no, output a driving signal to drive a third warning signal (Step 640); if yes, output a driving signal to drive a fourth warning signal (Step 642). A driving signal is output to the warning unit 230 by comparing the dB value of the digital sound source signal with the preset dB value of the memory module 222 so as to be able to show a warning signal or emit sound by means of sound, characters, graph and etc, Besides, each warning signal can be replaced by different color luminous bodies or different speech sounds. When a certain color luminous body is lighted or a certain speech sound is heard, a user can know the sound volume is between which dB values so as to judge whether the sound volume is inside hearing capability protection standard range to attain to the object of protecting the hearing safety of the user.

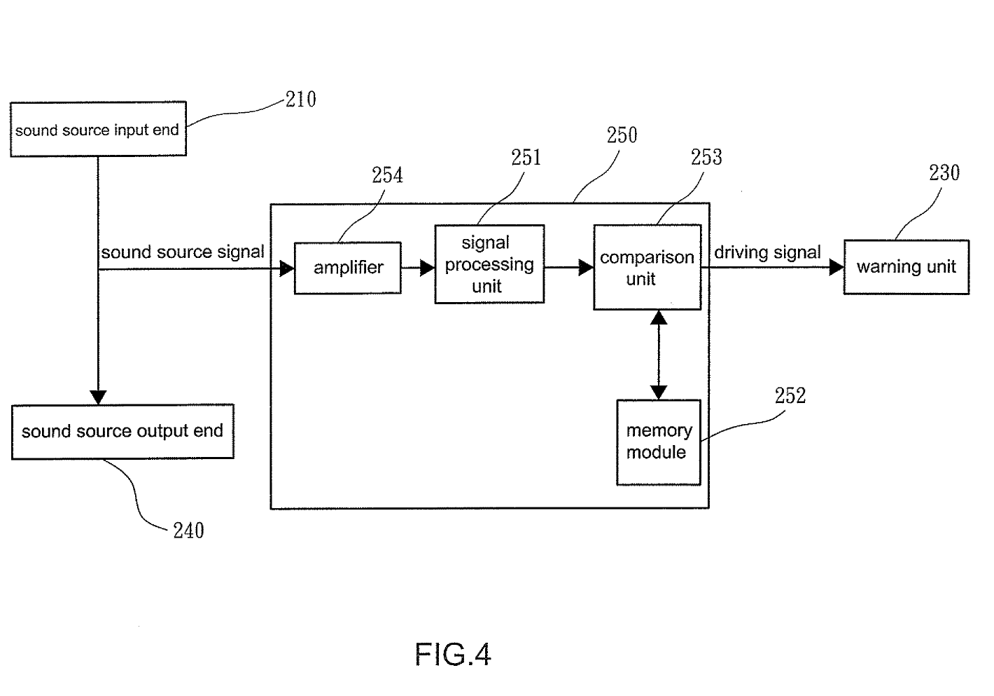

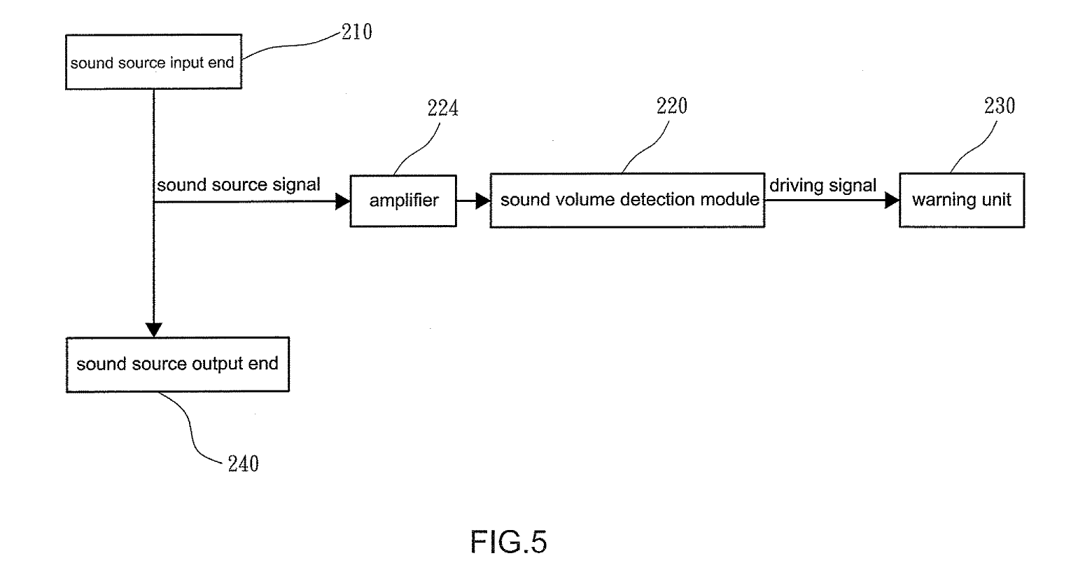

Next, please refer to FIG. 4. FIG. 4 is a block diagram showing a noise indication apparatus of a second preferred embodiment according to the present invention. The difference between the first and the second embodiments is in that an amplifier 254 used for amplifying the sound source signal is further disposed in the sound volume detection module 250 of the second embodiment, The comparison unit 253 is allowed to be easier to do the comparison with the preset dB values in the memory module 252 so as to decrease a measure error after the amplified sound source signal is transferred to be a corresponding dB value through the processing unit 251. Furthermore, please refer to FIG. 5. FIG. 5 is a block diagram showing a noise indication apparatus of a third preferred embodiment according to the present invention. Here, an amplifier 224 can also be disposed between the sound volume detection module 220 and the sound source input end 210.

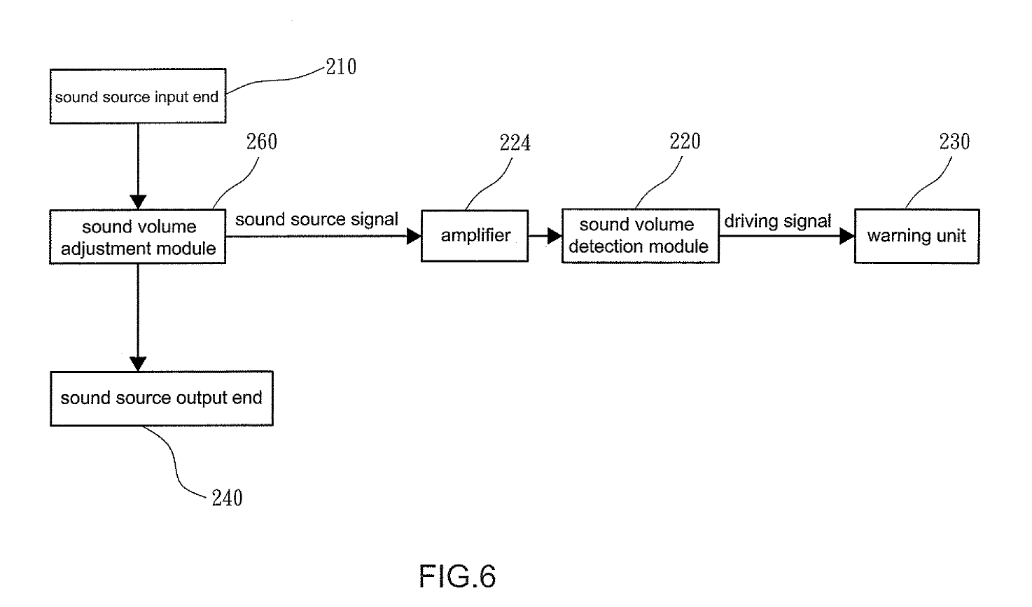

Finally, please refer to FIG. 6. FIG. 6 is a noise indication apparatus of a fourth preferred embodiment according to the present invention. A sound volume adjustment module 260 used for adjusting the sound volume of the sound source input end 210 is further disposed in the noise indication apparatus. The adjusted sound source signal can be transferred to the amplifier to be amplified through the amplifier 224 and then transferred through the sound volume detection module 220. A driving signal is yielded to drive the warning unit 230 depending on a comparison result after a comparison.

A noise indication apparatus of the present invention not only is easy to be operated and used, but also can allow a user to apply it on a current electronic device without needing to purchase additionally an electronic device with a sound volume detection module to enable it to be convenient on use.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A noise indication apparatus, comprising:
a sound source input end, used for inputting a sound source signal;
a sound output end, electrically connected with said sound source input end and used for receiving said sound source signal;
a sound volume detection module, electrically connected with said sound source input end, picking up said sound source signal, converting said sound source signal to be a digital sound source signal with a corresponding dB value, comparing said corresponding dB value with a preset dB value and outputting a driving signal depending on a comparison result; and
a warning unit, being a display element and electrically connected to said sound volume detection module, used for receiving said driving signal to display a warning signal.

2. The noise indication apparatus according to claim 1, wherein said sound volume detection module comprises:
a memory module, used for storing one and more than one preset dB value;
a signal processing unit, used for converting said sound source signal to be a dB value; and
a comparison unit, used for comparing said dB value obtained from said processing unit with said preset values, and generating a driving signal depending on a comparison result.

3. The noise indication apparatus according to claim 2, wherein said signal processing unit is an analog/digital converter.

4. The noise indication apparatus according to claim 2, further comprising an amplifier.

5. The noise indication apparatus according to claim 1, wherein said warning unit is a sound emitting element.

6. The noise indication apparatus according to claim 5, wherein said sound emitting element is a speaker or amplifier.

7. The sound indication apparatus according claim 1, wherein said sound detection module is a microprocessor.

8. The noise indication apparatus according to claim 1, wherein said display element is at least one LED or a luminescent element.

9. The noise indication apparatus according to claim 1, further comprising a sound adjustment module.

10. The noise indication apparatus according to claim 1, further comprising an amplifier.

11. A method for detecting noise, comprising the following steps: picking up a sound source signal;
converting said sound source signal to a digital signal and calculating out a corresponding dB value;
comparing a dB value of said sound source signal with one and more than one preset db Value; and
generating a driving signal depending on a comparison result to drive a warning unit to generate a warning signal.

12. The method for detecting noise according to claim 11, wherein amplify said sound source signal after picking up said sound source signal.

13. The method for detecting noise according to claim 11, wherein said warning signal is a warning sign or warning sound.
